(19) United States
(12) Patent Application Publication
(10) Pub. No.: US 2025/0285586 A1
(43) Pub. Date: Sep. 11, 2025

(54) METHOD OF DRIVING DISPLAY DEVICE, DISPLAY DEVICE PERFORMING THE SAME, ELECTRONIC APPARATUS INCLUDING THE SAME

(71) Applicant: Samsung Display Co., LTD., Yongin-si (KR)

(72) Inventors: CHUL SHIN, Yongin-si (KR); HWAAN SUNG, Yongin-si (KR); TAEWAN KIM, Yongin-si (KR); JEONGAH LEE, Yongin-si (KR)

(21) Appl. No.: 19/020,426

(22) Filed: Jan. 14, 2025

(30) Foreign Application Priority Data
Mar. 7, 2024 (KR) 10-2024-0032769

(51) Int. Cl. G09G 3/3208

(52) U.S. Cl. CPC G09G 3/3208; G09G 2320/041; G09G 2330/021

(57) ABSTRACT

A method of driving a display device includes: receiving input image data; generating temperature information for each of areas of a display pane of the display device; detecting a local temperature change based on the temperature information; and determining whether the local temperature change is a change due to the input image data.

### CROSS-REFERENCE TO RELATED APPLICATION

The present application claims priority to and the benefit of Korean Patent Application No. 10-2024-0032769, filed on Mar. 7, 2024, in the Korean Intellectual Property Office, the entire content of which is incorporated by reference herein.

### BACKGROUND

### 1. Field

The present disclosure relates to a display device, more specifically, to a method of driving a display device and a display device performing the same.

### 2. Description of Related Art

With the development of information technology, the importance of display devices, which are the medium of connection between users and information, is being highlighted. As a result, the use of display devices such as liquid crystal display devices (LCDs), organic light emitting display devices (OLEDs), and plasma display devices (PDPs) is increasing.

Although there is a notice that the display device should be wiped with a dry cloth, however a user using the display device may spray excessive detergent on the display device, causing a defect due to liquid such as the detergent.

### SUMMARY

Aspects and features of one or more embodiments of the present disclosure relate to a method of driving a display device that detects a local temperature change in order to prevent an occurrence of a defect by liquid.

Aspect and features of one or more embodiments of the present disclosure relate to a display device that implements the method of driving the display device.

However, the present disclosure is not limited thereto, and it may be expanded in various ways within the spirit and scope of the present disclosure.

A method of driving a display device according to one or more embodiments of the present disclosure includes receiving input image data, generating temperature information for each of areas of a display panel of the display device, detecting a local temperature change based on the temperature information, and determining whether the local temperature change is a change due to the input image data.

In one or more embodiments, the method may further include determining whether the local temperature change spreads in a longitudinal direction if the local temperature change is not the change due to the input image data, and the longitudinal direction may be parallel to a direction in which liquid flows on the display panel.

In one or more embodiments, the method may further include displaying a warning window if the local temperature change spreads in the longitudinal direction is determined.

In one or more embodiments, the warning window may display a message to remove liquid present in a first area of the areas of the display panel, and the first area may be an area where the local temperature change spreads in the longitudinal direction.

In one or more embodiments, the method may further include blocking power supply to the display panel if the local temperature change spreads in the longitudinal direction is determined.

In one or more embodiments, the temperature information for each of the areas of the display panel may include a first temperature information of a first area of the areas where liquid is present on the display panel and a second temperature information of at least one area of the areas of the display panel where the liquid is not present on the display panel, and the first temperature information and the second temperature information may have different values.

In one or more embodiments, the first temperature information may have a smaller value than the second temperature information.

In one or more embodiments, the first temperature information may be proportional to a first current value provided to a pixel at the first area, and the second temperature information may be proportional to a second current value provided to a pixel at a second area of the areas of the display panel.

A display device according to one or more embodiments of the present disclosure includes a display panel including a plurality of pixels, a power supply configured to supply power to the display panel, and a controller configured to receive input image data, generate temperature information for each of areas of the display panel, detect a local temperature change based on the temperature information, and determine whether the local temperature change is a change due to the input image data.

In one or more embodiments, the controller is configured to determine whether the local temperature change spreads in a longitudinal direction if the local temperature change is not the change due to the input image data, and the longitudinal direction may be parallel to a direction in which liquid flows on the display panel.

In one or more embodiments, the controller may further include a warning part that is configured to display a warning window if the local temperature change spreads in the longitudinal direction is determined.

In one or more embodiments, the warning window may be configured to display a message to remove liquid present in a first area of the areas of the display panel, and the first area may be an area where the local temperature change spreads in the longitudinal direction.

In one or more embodiments, the controller may further include a blocking part that is configured to block power supply to the display panel if the local temperature change spreads in the longitudinal direction is determined.

In one or more embodiments, the temperature information for each of the areas of the display panel may include a first temperature information of a first area of the areas where liquid is present on the display panel and a second temperature information of at least one area of the areas of the display panel where the liquid is not present on the display panel, and the first temperature information and the second temperature information may have different values.

In one or more embodiments, the first temperature information may have a smaller value than the second temperature information.

In one or more embodiments, the first temperature information may be proportional to a first current value provided to a pixel at the first area, and the second temperature information may be proportional to a second current value provided to a pixel at a second area of the areas of the display panel.

In one or more embodiments, each of the plurality of pixels may include an organic light-emitting material.

In one or more embodiments, the display device may further include a driving integrated circuit electrically connected with the display panel, and a penetration prevention member sealing a gap between the display panel and the driving integrated circuit.

In one or more embodiments, the penetration prevention member may include a silicon.

An electronic apparatus according to one or more embodiments of the present disclosure includes a display device including a display panel comprising a plurality of pixels, a processor configured to control the display device, a power supply configured to supply power to the display device, and a controller configured to transmit input image data to the display panel, generate temperature information for each of areas of the display panel, detect a local temperature change based on the temperature information, and determine whether the local temperature change is a change due to the input image data.

In one or more embodiments, the controller may be configured to determine whether the local temperature change spreads in a longitudinal direction if the local temperature change is not the change due to the input image data, the controller may be configured to commend to the display device to display a warning window including a message to remove liquid present in a first area of the areas of the display panel if the local temperature change spreads in the longitudinal direction is determined, the longitudinal direction may be parallel to a direction in which liquid flows on the display panel, and the first area may be an area where the local temperature change spreads in the longitudinal direction.

In one or more embodiments, the controller may be configured to determine whether the local temperature change spreads in a longitudinal direction if the local temperature change is not the change due to the input image data, the controller may be configured to commend to the power supply to block power supply to the display panel if the local temperature change spreads in the longitudinal direction is determined, and the longitudinal direction may be parallel to a direction in which liquid flows on the display panel.

In one or more embodiments, the temperature information for each of the areas of the display panel may include a first temperature information of a first area of the areas where liquid is present on the display panel and a second temperature information of at least one area of the areas of the display panel where the liquid is not present on the display panel and the first temperature information may have a smaller value than the second temperature information.

In one or more embodiments, the first temperature information may be proportional to a first current value provided to a pixel at the first area, and the second temperature information is proportional to a second current value provided to a pixel at a second area of the areas of the display panel.

A method of driving a display device, a display device performing the same, and an electronic apparatus including the same according to one or more embodiments of the present disclosure may receive input image data, generate temperature information for each of areas of a display panel of the display device, detect a local temperature change based on the temperature information, and determine whether the local temperature change is a change due to the input image data. Accordingly, liquid on the display panel included in the display device may be detected.

In addition, the method of driving the display device, the display device performing the same, and an electronic apparatus including the same according to one or more embodiments of the present disclosure may determine whether the local temperature change spreads in the longitudinal direction if the local temperature change is not the change due to the input image data. The longitudinal direction may be parallel to a direction in which liquid flows on the display panel. Accordingly, whether the local temperature change is due to the liquid or the input image date may be possible to distinguish.

In addition, the method of driving the display device, the display device performing the same, and an electronic apparatus including the same according to one or more embodiments of the present disclosure may display the warning window if the local temperature change spreads in the longitudinal direction is determined. The warning window may display the message to remove the liquid present in the first area of the areas of the display pane. The first area may be the area where the local temperature change spreads in the longitudinal direction. By instructing the user to remove the liquid, to prevent the defect in the display device caused by the liquid may be possible.

In addition, the method of driving the display device, the display device performing the same, and an electronic apparatus including the same according to one or more embodiments of the present disclosure may block the power supply to the display panel if the local temperature change spreads in the longitudinal direction is determined. By blocking the power supply, to prevent the defect in the display device caused by the liquid may be possible.

However, aspects, embodiments, and/or effects of the present disclosure are not limited to the above-described effects, and may be variously expanded without departing from the spirit and scope of the present disclosure.

### BRIEF DESCRIPTION OF THE DRAWINGS

FIG. 1 is a flowchart illustrating a method of driving a display device according to one or more embodiments of the present disclosure.

FIGS. 2, 3, 4, 5, 6, and 7 are views illustrating the method of driving a display device according to the method of FIG. 1.

FIG. 8 is a block diagram illustrating an electronic apparatus according to one or more embodiments of the present disclosure.

FIG. 9 is a plan view illustrating an example in which the electronic apparatus of FIG. 9 is implemented as a smart phone.

FIG. 10 is a block diagram illustrating a controller included in the display device of FIG. 9.

FIG. 11 is a cross-sectional view taken along the line I-I′ of FIG. 9.

FIG. 12 is a view illustrating a light emitting layer included in FIG. 11.

FIG. 13 is a cross-sectional view taken along the line II-II′ of FIG. 9.

### DETAILED DESCRIPTION

Hereinafter, embodiments of the present disclosure will be described in more detail with reference to the accompanying drawings. These embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

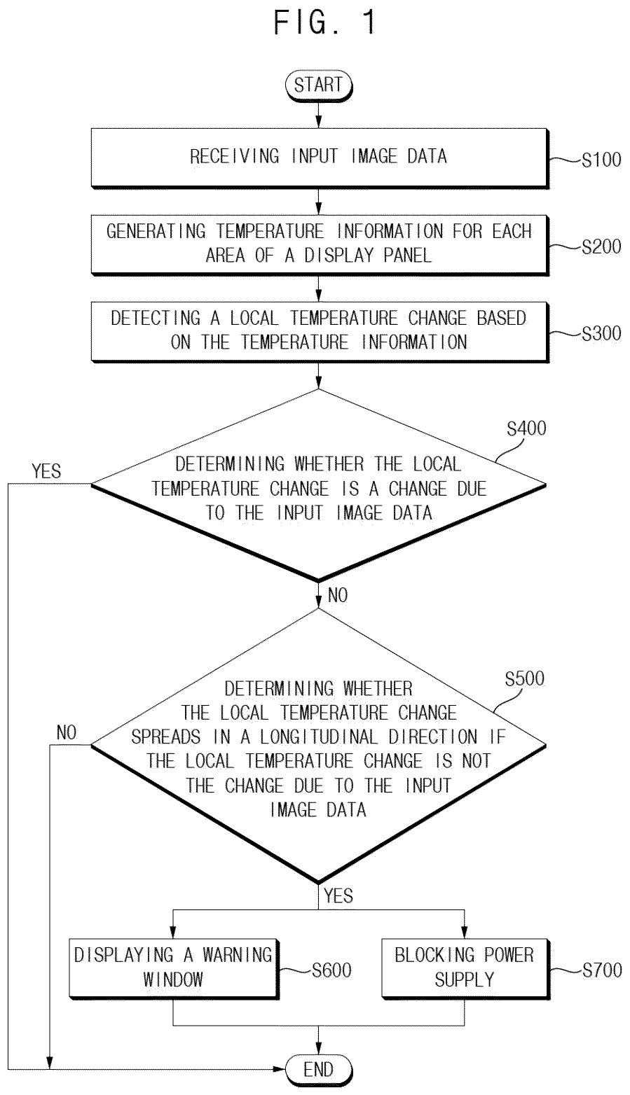

FIG. 1 is a flowchart illustrating a method of driving a display device according to one or more embodiments of the present disclosure.

Referring to FIG. 1, in one or more embodiments, the method of driving the display device may include following steps. Specifically, the method of driving the display device may include receiving input image data (S100), generating temperature information for each area of a display panel (S200), detecting a local temperature change based on the temperature information (S300), and determining whether the local temperature change is a change due to the input image data (S400).

In one or more embodiments, the method of driving the display device may further include determining whether the local temperature change spreads in a longitudinal direction if the local temperature change is not the change due to the input image data (S500). The longitudinal direction may be parallel to a direction in which liquid flows on the display panel.

For example, the liquid may be a detergent. A user of the display device may spray the detergent on the display device. The detergent may penetrate into the display device or come into contact with a data pad included in the display device, causing a defect such as data line defects, burnt, and/or the like.

In one or more embodiments, the method of driving the display device may further include displaying a warning window if the local temperature change spreads in the longitudinal direction is determined (S600).

In one or more embodiments, the method of driving the display device may further include blocking power supply to the display panel if the local temperature change spreads in the longitudinal direction is determined (S700).

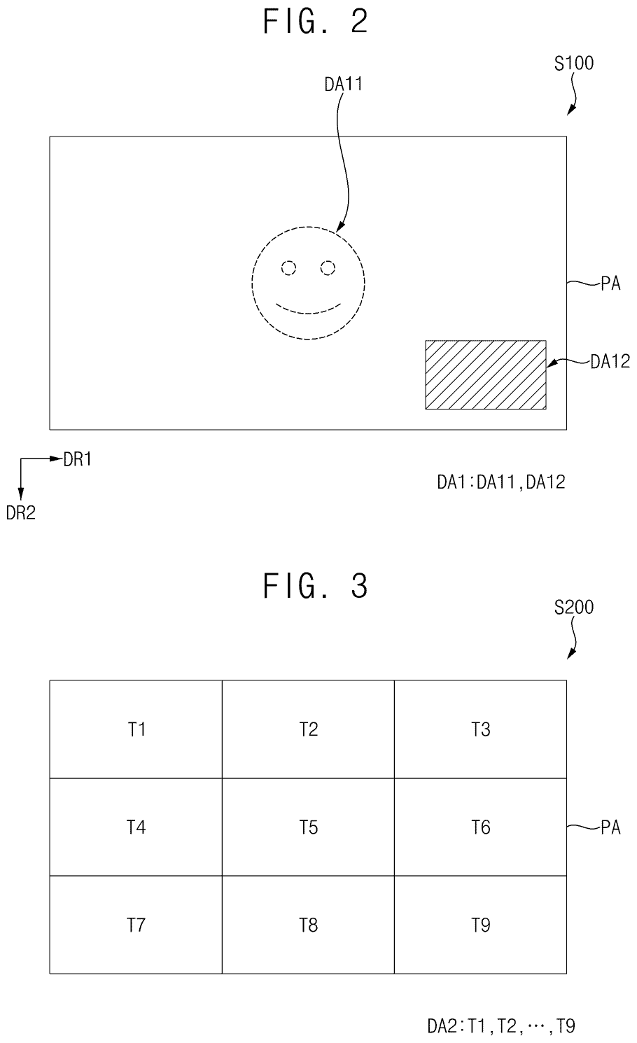

FIGS. 2, 3, 4, 5, 6, and 7 are views illustrating the method of driving a display device according to the method of FIG. 1.

Referring to FIG. 2, in one or more embodiments, the method of driving the display device may include receiving input image data DA1 (S100). The input image data DA1 may be input from an outside. For example, the input image data DA1 may be input from a graphic memory. However, the present disclosure is not limited thereto.

For example, the input image data DA1 may be divided into a plurality of portions (e.g., 9 portions in FIG. 3) determined by a size, resolution, and/or the like, of the display device. For example, the input image data DA1 may be divided into portions of about 16× (multiply) about 18 (about 288 portions). A plurality of pixels may be located in a single area (e.g., one portion). However, the present disclosure is not limited thereto. The number and size of the portions may be variously changed.

The input image data DA1 may be n-bit digital data in which m grayscale levels (e.g., gray levels) may be expressed. For example, if the input image data DA1 is about 8 bits of data capable of expressing R, G, and B, the input image data of R, G, and B may express about 28, i.e., about 256 grayscales. However, the present disclosure is not limited thereto. The number of bits per pixel may vary widely.

A display panel PA included in the display device may receive the input image data DA1 and display the image corresponding to the input image data DA1. For example, the input image data DA1 may include a first image DA11 and a second image DA12. For example, in the second image DA12, oblique lines displaying a black grayscale level may have smaller grayscale levels (e.g., gray levels) than between the oblique lines displaying a white grayscale level.

For example, as the grayscale levels (e.g., gray levels) increase, a greater current may flow to the light-emitting device included in the display device. For example, when expressing the white grayscale level on the light-emitting device, a greater current may flow than when the black grayscale level is expressed.

Referring to FIGS. 3 and 4, in one or more embodiments, the method of driving the display device may generate temperature information DA2 for each area (e.g., a first portion PO1 to a ninth portion PO9 of FIG. 6) of the display panel PA (S200), and the local temperature change may be detected based on the temperature information DA2 for each area (S300).

In one or more embodiments, the temperature information DA2 for each area of the display panel PA may include a first temperature information (e.g., T1) of the first area (e.g., the first portion PO1) where the liquid is present on the display panel PA and a second temperature information (e.g., T2, T3, T4, T5, T6, T7, T8, and/or T9) of the second area (e.g., the second to ninth portions PO2, PO3, PO4, PO5, PO6, PO7, PO8, and/or PO9) where the liquid is not present on the display panel PA, and the first temperature information (e.g., T1) and the second temperature information (e.g., T2, T3, T4, T5, T6, T7, T8, and/or T9) may have different values (e.g., temperatures).

In one or more embodiments, the first temperature information (e.g., T1) may have a smaller value than the second temperature information (e.g., T2, T3, T4, T5, T6, T7, T8, and/or T9). In one or more embodiments, the first temperature information (e.g., T1) and the second temperature information (e.g., T2, T3, T4, T5, T6, T7, T8, and/or T9) may be proportional to a first current value provided to the pixels disposed in the first area (e.g., the first portion PO1) and a second current value provided to the pixel disposed in the second area (e.g., the second to ninth portions PO2, PO3, PO4, PO5, PO6, PO7, PO8, and/or PO9).

Referring to FIGS. 2, 5, and 6, in one or more embodiments, the method of driving the display device may determine whether the local temperature change is the change due to the input image data DA1 (S400). The method of driving the display device may determine whether the local temperature change spreads in a longitudinal direction (e.g., a second direction DR2) if the local temperature change is not the change due to the input image data DA1 (S500). As described above, the longitudinal direction may be parallel to a direction in which liquid LI flows on the display panel PA (e.g., the second direction DR2).

As described above, the local temperature change may be caused by displaying a low-grayscale level (e.g., the black grayscale level), or may be caused by a presence of the liquid LI on the display panel PA.

The method of driving the display device according to one or more embodiments of the present disclosure may detect the local temperature change by the liquid LI other than the input image data DA1. In other words, the method of driving the display device according to one or more embodiments of the present disclosure may distinguish whether the local temperature change is the change by the liquid LI or the change by the input image data DA1, and may prevent the occurrence of the defect of the display device due to the liquid LI by detecting the liquid LI on the display device LI in advance.

Referring to FIGS. 5, 6, and 7, in one or more embodiments, the method of driving the display device may display a warning window AM if the local temperature change spreads in the longitudinal direction (e.g., the second direction DR2) is determined (S600).

In one or more embodiments, the warning window AM may display a message to remove the liquid present in the first area (e.g., the first portion PO1) from among the areas (e.g., the first portion PO1 to ninth portion PO9) of the display panel PA. The first area may be the area where the local temperature change spreads in the longitudinal direction.

As described above with reference to FIG. 1, in one or more embodiments, the method of driving the display device may block the power supply that supplies power to the display panel PA if the local temperature change spreads in the longitudinal direction is determined (S700).

The method of driving the display device according to one or more embodiments of the present disclosure may inform (e.g. induce or advice) the user to remove the liquid LI and prevent the occurrence of the defect of the display device due to the liquid LI in advance. In addition, the method of driving the display device according to one or more embodiments of the present disclosure may prevent the occurrence of the defect of the display device due to the liquid LI by blocking the power supply of the display device in advance.

In the above, it was explained that the display panel PA is divided into nine areas, however the present disclosure is not limited thereto. As described above, the size, number, and/or the like, of the portion areas may vary depending on the resolution, size, and/or the like, of the display device.

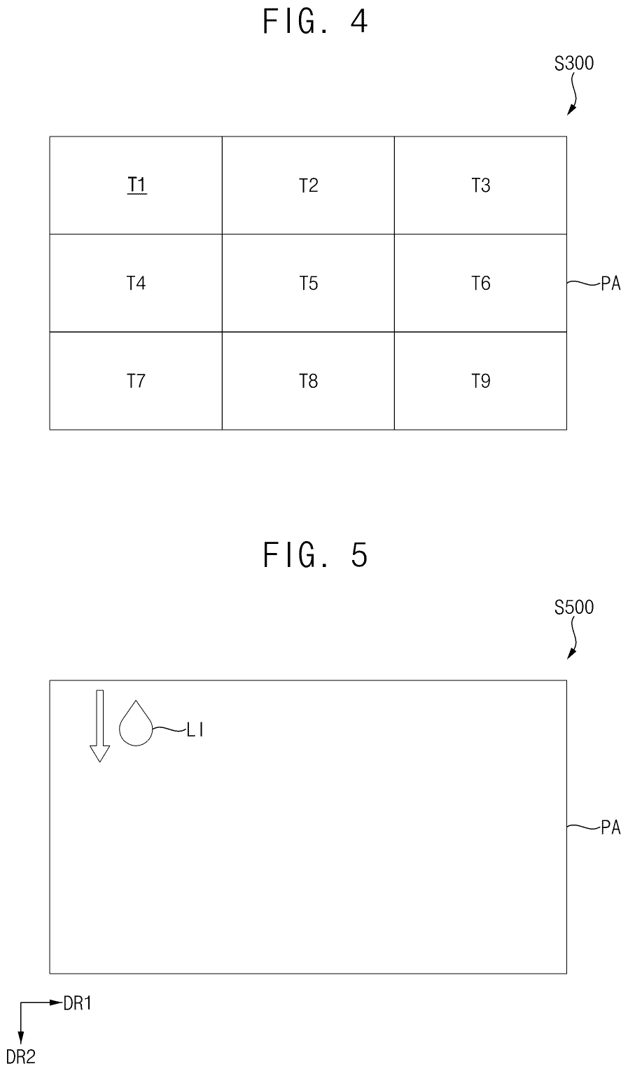

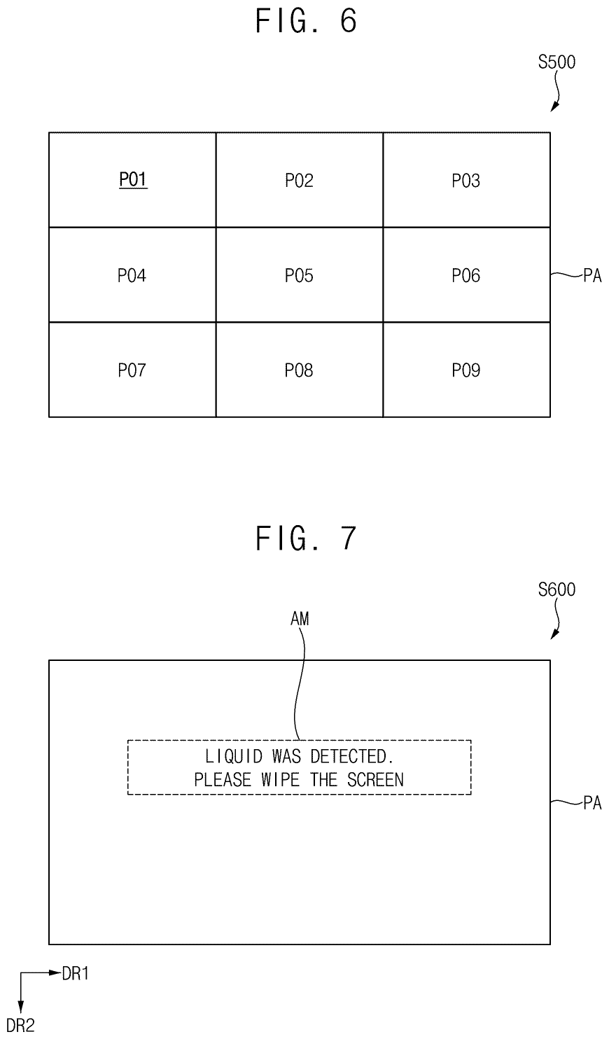

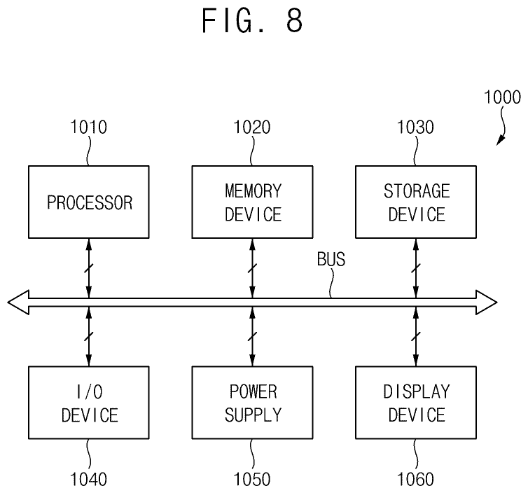

FIG. 8 is a block diagram illustrating an electronic apparatus according to one or more embodiments of the present disclosure. FIG. 9 is a plan view illustrating an example in which the electronic apparatus of FIG. 9 is implemented as a smart phone. FIG. 10 is a block diagram illustrating a controller included in the display device of FIG. 9.

Referring to FIG. 8, an electronic apparatus 1000 may include a processor 1010, a memory device 1020, a storage device 1030, an input/output (I/O) device 1040, a power supply 1050, and a display device 1060.

Here, the display device 1060 may be the display device performing the method of driving the display device of FIG. 1.

In addition, the electronic apparatus 1000 may further include a plurality of ports for communicating with a video card, a sound card, a memory card, a universal serial bus (USB) device, other electronic apparatuses, etc.

In one or more embodiments, as illustrated in FIG. 9, the electronic apparatus 1000 may be implemented as a smart phone. However, the electronic apparatus 1000 is not limited thereto. For example, the electronic apparatus 1000 may be implemented as a cellular phone, a video phone, a smart pad, a smart watch, a tablet PC, a car navigation system, a computer monitor, a laptop, a head mounted display (HMD) device, and/or the like.

The processor 1010 may perform various computing functions or various tasks. The processor 1010 may be a micro-processor, a central processing unit (CPU), an application processor (AP), and/or the like. The processor 1010 may be coupled to other components via an address bus, a control bus, a data bus, and/or the like. Further, the processor 1010 may be coupled to an extended bus such as a peripheral component interconnection (PCI) bus.

The processor 1010 may output the input image data (e.g., the DA1 of FIG. 2) and the input control signal to the input device.

The memory device 1020 may store data for operations of the electronic apparatus 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 1030 may include a solid state drive (SSD) device, a hard disk drive (HDD) device, a CD-ROM device, and/or the like.

The I/O device 1040 may include an input device such as a keyboard, a keypad, a mouse device, a touch-pad, a touch-screen, and/or the like and an output device such as a printer, a speaker, and/or the like. In some embodiments, the display device 1060 may be included in the I/O device 1040.

The power supply 1050 may supply power for operations of the electronic apparatus 1000.

The display device 1060 may be coupled to other components via the buses or other communication links.

In FIG. 9, the electronic apparatus of the present disclosure is implemented as a smartphone, however, the present disclosure is not limited thereto. The electronic apparatus may be a television, a monitor, a laptop computer, a tablet, a car, and/or the like.

Hereinafter, for convenience of explanation, the description will focus on the display device 1060 from among the components of the electronic apparatus 1000 implemented as the smartphone. In addition, descriptions that overlap with the description of the method of driving the display device described above with reference to FIGS. 1, 2, 3, 4, 5, 6, and 7 will be omitted or simplified.

Referring to FIGS. 1, 8, 9, and 10, in one or more embodiments, the display device 1060 may include the display panel PA, a driving integrated circuit CH, the power supply (e.g. the power supply 1050 of FIG. 8), the controller (e.g., the processor 1010 of FIG. 8), and a penetration prevention member PP.

For example, the display panel PA may have a variety of planar shapes. For example, the display panel PA may have a rectangular shape. However, the present disclosure is not limited thereto. For example, the display panel PA may have a variety of shapes, such as round and/or oval. In addition, corners of the display panel PA may have an angular shape or a curved shape.

For example, the display panel PA may be a flexible display device. In this case, at least one area of the display panel PA may be deformable. Specifically, the display panel PA may be folded or bent. However, the present disclosure is not limited thereto. For example, the display panel PA may be a rigid display device.

The display panel PA may include a display area DA and a non-display area NDA disposed around the display area DA along an edge or a periphery of the display area DA.

In one or more embodiments, the display panel PA may include a gate line, a data line, and a plurality of pixels PX.

For example, the display area DA may be an area in which an image is displayed. For this purpose, the plurality of pixels PX may be disposed in the display area DA. For example, the display panel PA may be an organic light-emitting display device including an organic light-emitting diode (OLED). However, the present disclosure is not limited thereto. The display panel PA may include various types of pixels. For another example, multiple pixels PX may also be disposed in the non-display area NDA.

For example, the gate line may extend in a first direction DR1 crossing the second direction DR2. For example, the data line may extend in the second direction DR2. The first direction DR1 may cross the second direction DR2. For example, the first direction DR1 and the second direction DR2 may be perpendicular to each other. For example, each of the plural pixels PX may be electrically connected to the data line and the gate line.

For example, each of the plural pixels PX may include a drive transistor and a light-emitting device. For example, the drive transistor may generate a drive current in response to a data voltage. For example, the light-emitting device may emit light based on a drive current.

The non-display area NDA may be an area where an image is not displayed. In the non-display area NDA, a circuit structure (e.g., a line, the pad, the driving circuit, and/or the like) may be disposed to drive the plurality of pixels PX. In order to prevent the circuit structure and/or the like from being visible to the outside of the display panel PA, the non-display area NDA may include a black ink layer. However, the present disclosure is not limited thereto. For example, the ink layer may be omitted, and the circuit structure may be disposed at a different location.

The non-display area NDA may be adjacent to the display area DA. For example, the non-display area NDA may be around (e.g., may surround) the display area DA. However, the present disclosure is not limited thereto. For example, the non-display area NDA may be disposed only on one side of the display area DA.

One end of the driving integrated circuit CH may be bonded between pads disposed in one area of the display panel PA and electrically connected to the display panel PA. However, the present disclosure is not limited thereto. For example, the driving integrated circuit CH may be electrically connected by direct contact with the display panel PA without any additional pads.

The driving integrated circuit CH may include a driving circuit. In one or more embodiments, the driving circuit may be connected to the display panel PA in a chip-on-plastic (COP) manner. The chip-on-plastic manner may mean a method in which the driving circuit and the display panel PA including the plastic are directly connected. However, the present disclosure is not limited thereto. For example, the driving circuit may be connected to the display panel PA in various ways, such as the chip-on-glass (COG) method that is integrated with the display panel PA including a glass, and the chip-on-film (COF) method that is implemented as the integrated circuit and mounted on the driving integrated circuit CH.

In the FIG. 8, the power supply (e.g., 1050 of FIG. 8) and the controller (e.g., the processor 1010 of FIG. 8) are described as being provided separately from the display device 1060, however the present disclosure is not limited thereto. For example, the power supply (e.g., 1050 of FIG. 8) and the controller (e.g., the processor 1010 of FIG. 8) may be embedded in the display device 1060. For example, as shown in FIG. 10, the controller CO may also be implemented as a separate device.

In one or more embodiments, the power supply (e.g., the power supply 1050) may supply the power to the display panel PA (including the display device). For example, the power supply (e.g., the power supply 1050) may be a battery. The battery may be adjacent to the driving integrated circuit CH on the display panel PA.

The controller CO may control an operation of the display device 1060. For example, the controller CO may include a drive controller, a gate driver, and a data driver. In one or more embodiments, the controller CO may include a first controller 1012, a second controller 1014, and a third controller 1016.

For example, the drive controller may receive the input image data DA1 and input control signal. For example, as described above, the input image data DA1, may include red image data, green image data, and blue image data. For another example, the input image data DA1 may also include white image data. For another example, input image data DA1 may also include magenta, yellow, and/or cyan image data. The input control signal may include a master clock signal, a data-enabling signal, and/or the like. The input control signal may further include a vertical synchronous signal, a horizontal synchronous signal, and/or the like. The drive controller may generate data signals, various control signals, and/or the like, based on the input image data DA1 and the input control signal. The signals may be provided to other driving parts, and/or the like.

For example, on the basis of the data signal, a data voltage in analog form may be generated. The data voltage may be provided to each of the plural pixels PX via the data line. For example, the data voltage may be generated by the data drive. The data driver may be implemented as a timing controller embedded data driver (TED). However, the present disclosure is not limited thereto.

In one or more embodiments, the controller CO may receive the input image data DA1 provided (transmitted) to the display panel PA. As shown in FIGS. 2 and 10, the first controller 1012 may receive the input image data (e.g., the input image data DA1) from the outside and provide it to the display panel PA.

In one or more embodiments, the controller CO may generate temperature information DA2 for each areas of the display panel PA. As shown in FIGS. 3 and 10, the second controller 1014 may generate temperature information DA2 for each areas of the display panel PA. For example, if the display panel PA is divided into approximately nine areas, the temperature information DA2 may also generate about nine pieces of data. The temperature information DA2 may be updated in approximately 5-second increments. However, the present disclosure is not limited thereto. For example, the number of temperature information DA2 data, the frequency of updates, and/or the like, may vary variously.

In one or more embodiments, the controller CO may detect a local temperature change (e.g., T1) based on the temperature information DA2 and determine whether the local temperature change (e.g., T1) is a change due to input image data (e.g., DA1 of FIG. 2). As shown in FIGS. 4 and 10, the third controller 1016 may detect the local temperature changes (e.g., T1).

For example, as described in FIG. 2, the local temperature change may be caused by displaying a low grayscale level (e.g., the black grayscale level) or may be caused by the presence of the liquid LI on the display panel PA as shown in FIG. 5. The controller CO may detect that the local temperature change occurred in the liquid LI and not in the input image data, and inform (e.g. induce or advice) the user to wipe the display device to prevent the occurrence of defects by the liquid LI.

Specifically, as shown in FIG. 5, in one or more embodiments, the controller CO may determine whether the local temperature change spreads in the longitudinal direction if the local temperature change is not the change due to the input image data. The longitudinal direction (e.g., the second direction DR2) may be parallel to the direction in which the liquid LI flows on the display panel PA.

As described above by reference to FIGS. 1, 2, 3, 4, 5, 6, and 7, in one or more embodiments, the temperature information DA2 for each area of the display panel PA may include the first temperature information T1 of the first area (e.g. the first portion PO1) where the liquid LI is present on the display panel PA and the second temperature information T2, T3, T4, T5, T6, T7, T8, and/or T9 of the second area (e.g., the second to ninth portions PO2, PO3, PO4, PO5, PO6, PO7, PO8, and/or PO9), and the first temperature information T1 and the second temperature information T2, T3, T4, T5, T6, T7, T8, and T9 may have different values. In one or more embodiments, the first temperature information T1 may have a smaller value than the second temperature information T2, T3, T4, T5, T6, T7, T8, and T9.

In one or more embodiments, the first temperature information T1 may be proportional to the first current value provided to the pixels (e.g., PX of FIG. 9) disposed in the first area (e.g. the first portion PO1). The second temperature information T2, T3, T4, T5, T6, T7, T8, and T9 may be proportional to the second current value provided to the pixels (e.g., PX of FIG. 9) disposed in the second area (e.g. the second to ninth portions PO2, PO3, PO4, PO5, PO6, PO7, PO8, PO9).

In order to store the temperature information, the current value, and/or the like, a non-volatile memory may be disposed in the controller CO. For example, the non-volatile memory may be flash memory. However, the present disclosure is not limited thereto. For example, the controller CO may include a volatile memory. For example, the volatile memory may be RAM, SAM, and/or the like.

For example, if the temperature information DA2 collected for a suitable time (e.g., a predetermined time) shows a tendency for the temperature to decrease toward the first portion PO1, the second portion PO2, and the third portion PO3, whether the input image data DA1 indicates that the low grayscale level is displayed in the first to third portions PO1, PO2, and/or PO3 may be confirmed. If the local temperature change (e.g., the tendency for temperature to decrease toward the first to third portions PO1, PO2, PO3) is not the change due to the input image data, it may be determined that the liquid LI falls into the first portion PO1, passes through the second portion PO2, and flows down to the third portion PO3 (e.g., the local temperature change spreads in the longitudinal direction is determined). In such a case, PO1, PO2, PO3 may be arranged in the longitudinal direction according to one or more embodiments.

In one or more embodiments, the controller CO may further include a warning part that displays a warning window (e.g., a warning window AM of FIG. 7) if the local temperature change spreads in the longitudinal direction is determined. For example, third controller 1016 may generate a signal DA3 to display the warning window AM of FIG. 7 if the local temperature change is not the change by the input image data. In other words, the controller CO may commend to the display device to display the warning window including a message.

In one or more embodiments, the warning window may display the message to remove liquid (e.g., the liquid LI of FIG. 5) present in the first area (e.g., the first portion PO1 of FIG. 6) of the areas of the display panel, and the first area may be the area where the local temperature change spreads in the longitudinal direction.

In FIG. 7, “LIQUID WAS DETECTED. PLEASE WIPE THE SCREEN” is displayed in the warning window AM, however, the present disclosure is not limited thereto. For example, the message may be changed to various phrases that may inform (e.g. induce or advice) the user to wipe off the liquid on the display panel (e.g., the liquid LI on the display panel PA of FIG. 5).

In one or more embodiments, the controller CO may include a blocking part that blocks power supply to the display panel if the local temperature change spreads in the longitudinal direction is determined. For example, the fourth controller 1018 may generate a signal DA4 to disconnect the power to the display panel PA if the local temperature change is not the change due to the input image data. In other words, the controller CO may commend to the power supply to block the power supply to the display panel.

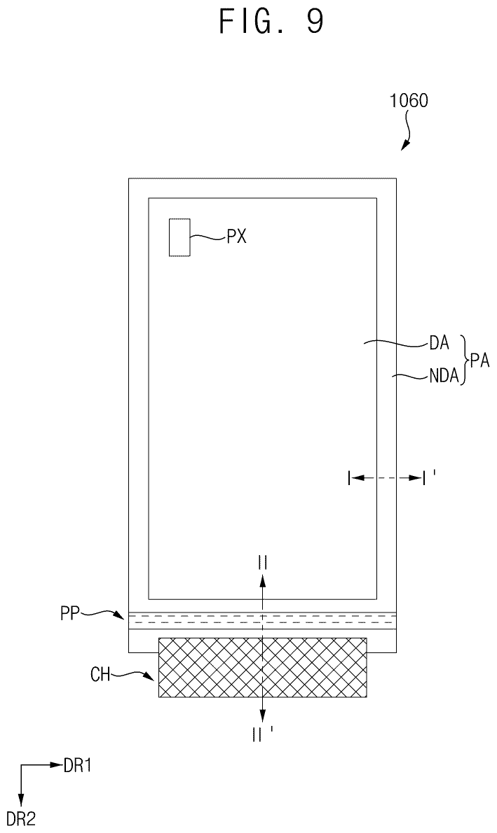

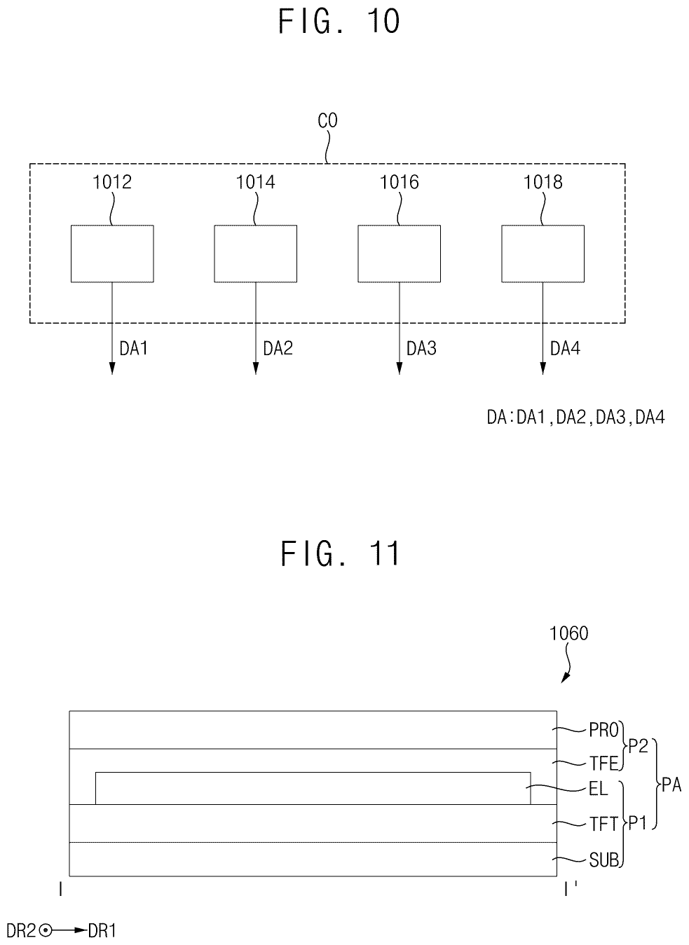

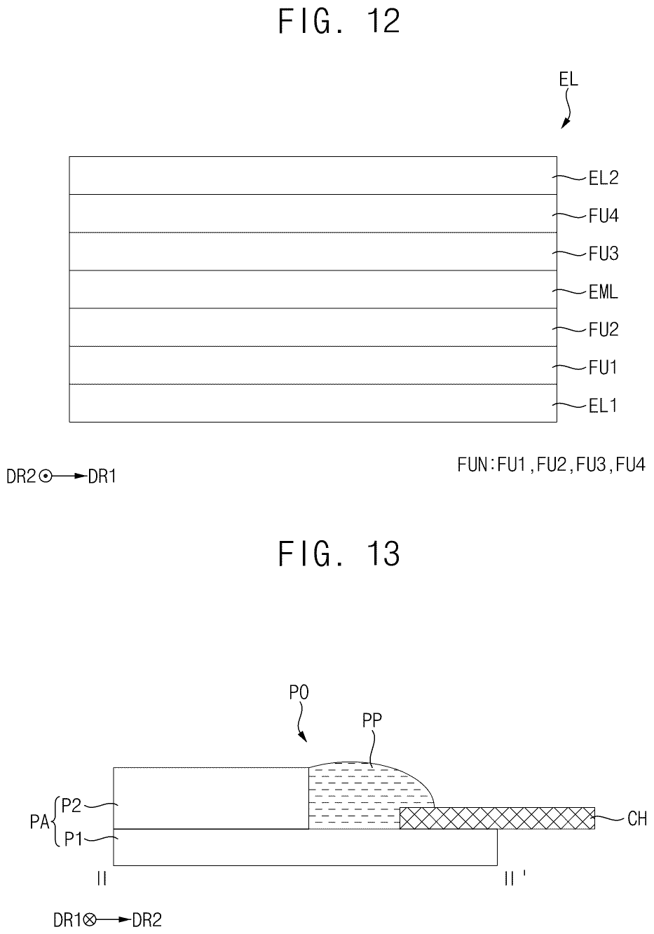

FIG. 11 is a cross-sectional view taken along the line I-I′ of FIG. 9. FIG. 12 is a view illustrating a light emitting layer included in FIG. 11. FIG. 13 is a cross-sectional view taken along the line II-II′ of FIG. 9.

Referring to FIGS. 9, 11, 12, and 13, in one or more embodiments, the display device 1060 may include the display panel PA including a lower plate P1 and an upper plate P2, the driving integrated circuit CH electrically connected to the display panel PA, and the penetration prevention member PP.

Hereinafter, descriptions that overlap with the description of the method of driving the display device described above with reference to FIGS. 1, 2, 3, 4, 5, 6, and 7, and the electronic apparatus 1000 and the display device 1060 described above with reference to FIGS. 8, 9, and 10 will be omitted or simplified.

For example, the display panel PA may have a structure in which a substrate SUB, a circuit wiring layer TFT, a light-emitting layer EL, encapsulation layer TFE, and protective layer PRO are stacked.

For example, the display panel PA may be a flexible display. In this case, the substrate SUB and encapsulation layer TFE included in the display panel PA may include a material with flexible properties.

For example, the substrate SUB may include polymeric organic matter, plastics, and/or the like. Specifically, the substrates SUB may include polyether sulphone (PES), polyacrylate (PA), polyether imide (PEI), polyethylene naphthalate (PEN), polyethylene terephthalate (PET), poly phenylene sulfide (PPS), polyarylate (PAR), polyimide (PI), polycarbonate (PC), cellulose tri acetate (CTA), cellulose acetate propionate (CAP), and/or the like. These may be used alone or in combination with each other. However, the present disclosure is not limited thereto.

For example, the substrate SUB may have a multi-layered structure. For example, the substrate SUB may include a first base substrate, a buffer layer, and/or a second base substrate. However, the present disclosure is not limited thereto.

The circuit wiring layer TFT may be disposed on the substrate SUB. For example, the circuit wiring layer TFT may include a transistor, a data line, a gate line, a power line, and/or the like, that make up each of the plural pixels PX. However, the present disclosure is not limited thereto. The circuit wiring layer TFT may further include control lines that control each of the plurality of pixels PX.

The light-emitting layer EL may be disposed on the circuit wiring layer TFT. The light-emitting layer EL may include a first electrode EL1, a light-emitting material layer EML, and a second electrode EL2. Electrons and holes introduced from the first electrode EL1 and the second electrode EL2 may combine in the light-emitting material layer EML to generate the light.

The first electrode EL1 may be disposed on the substrate SUB. For example, the first electrode EL1 may be an anode.

For example, the first electrode EL1 may include highly reflective metals. The highly reflective metals may include silver (Ag), magnesium (Mg), aluminum (AI), platinum (Pt), palladium (Pd), gold (Au), nickel (Ni), neodymium (Nd), iridium (Ir), chromium (Cr), and/or the like. These may be used alone or in combination with each other. However, the present disclosure is not limited thereto.

However, the present disclosure is not limited thereto. For example, if the display panel PA has a back-emitting structure, the first electrode EL1 may include a conductive oxide. For example, the conductive oxide may include indium tin oxide, indium zinc oxide, zinc oxide, indium oxide, indium oxide, indium gallium oxide, aluminum zinc oxide, and/or the like. These may be used alone or in combination with each other. However, the present disclosure is not limited thereto.

In one or more embodiments, each of the plural pixels (e.g., PX of FIG. 9) may include an organic light-emitting material. For example, the light-emitting device may be an organic light emitting diode (OLED). However, the present disclosure is not limited thereto. The light-emitting device may include a variety of materials. For example, the light-emitting device may be a nano light emitting diode (NED), a quantum dot-light emitting diode (QD-LED), a micro light emitting diode, an inorganic light-emitting diodes, and/or the like.

The light-emitting layer EL may be disposed on the first electrode EL1. For example, The light-emitting layer EL may include the organic light-emitting material.

The light-emitting layer EL may further include functional layers FUN. The functional layers FUN may be an auxiliary layer that helps the luminescence of the light-emitting layer EL. For example, the functional layer FUN may include a first functional layer FU1, a second functional layer FU2, a third functional layer FU3, and a fourth functional layer FU4. For example, the first functional layer FU1 may be a hole injection layer (HIL), the second functional layer FU2 may be the hole transport layer (HTL), and The third functional layer FU3 may be the electron transport layer (ETL), and the fourth functional layer FU4 may be the electron injection layer (EIL). However, the present disclosure is not limited thereto. For example, type, number, and order of arrangement of the auxiliary layers included in the functional layer FUN may be variously changed.

The second electrode EL2 may be disposed on the light-emitting material layer EML. For example, the second electrode EL2 may be a cathode.

For example, the second electrode EL2 may include a conductive oxide. However, the present disclosure is not limited thereto. For example, if the display panel PA has a back-emitting structure, the second electrode EL2 may include the highly reflective metal. For example, the second electrode EL2 may include silver (Ag).

An encapsulation layer TFE may be disposed on top of the light-emitting layer EL. As described above, the light-emitting layer EL may include the organic light-emitting material. The organic light-emitting material may be altered by moisture and/or oxygen, and/or the like. In order to prevent this, the light-emitting layer EL may be covered by the encapsulating layer TFE.

In the case of the flexible display, the encapsulated layer TFE may include a material having the flexible properties.

For example, the encapsulation layer TFE may have a single-layer structure. For example, the encapsulation layer TFE may be an inorganic film with a single-layer structure. The encapsulation layer TFE including the inorganic film may have a large mechanical strength. For example, the inorganic film may include silicon nitride (SiNₓ), silicon oxide (SiOxN_{y}), and/or the like. These may be used alone or in combination with each other. For another example, the encapsulation layer TFE may be an organic film with the single-layer structure. For example, the organic film may include acrylates, and/or the like. An upper surface of the encapsulation layer TFE including the organic film may be flat.

However, the present disclosure is not limited thereto. For another example, the encapsulation layer TFE may have a multi-layer structure. For example, the encapsulation layer TFE may include at least one inorganic film and at least one organic film. The encapsulation layer TFE having the multi-layer structure may have greater seal-ability (e.g., property of preventing a foreign material from entering the light-emitting layer EL) than the encapsulation layer TFE having the single-layer structure.

The protective layer PRO may be disposed on the encapsulation layer TFE. For example, the protective layer PRO may include a polymer material. For example, the protective layer PRO may include polymethyl methacrylate (PMMA), polyvinylidene chloride (PVDC), polyvinylidene fluoride (PVDF), polystyrene (PS), Polyacrylate (PA), polyether imide (PEI), polyethylene naphthalate (PEN), polyethylene terephthalate (PET), poly phenylene sulfide (PPS), polyarylate (PAR), polyimide (PI), poly carbonate (PC), ethylene-vinyl alcohol copolymer, and/or the like. These may be used alone or in combination with each other. However, the present disclosure is not limited thereto.

The protective layer PRO may protect the light-emitting layer EL from moisture and/or oxygen. However, the present disclosure is not limited thereto. In FIG. 11, it is shown that the protective layer PRO is disposed only on the top of the encapsulation layer TFE (i.e., the upper part of the display panel PA), however, the protective layer PRO may also be disposed on the lower part of the display panel PA. In this case, the protective layer PRO may serve as a support for components included in the display panel PA. For example, The protective layer PRO may be provided in the form of a film.

In one or more embodiments, the penetration prevention member PP may seal a gap between the display panel PA and the driving integrated circuit CH (e.g., see FIG. 13). For example, the penetration prevention member PP may include a water-repellent material. In one or more embodiments, the penetration prevention member PP may include silicone.

The penetration prevention member PP may prevent a penetration of the liquid (e.g., the liquid LI of FIG. 5) into an interior of the display device 1060. However, if a mini gap PO occurs, or an area not covered by the penetration prevention member PP occurs, the liquid may penetrate into the interior of the display device 1060 or flow down to the driving integrated circuit CH and cause a defect such as a corrosion of the data line, bunts, and/or the like.

On the other hand, unlike the display device 1060 described above with reference to FIGS. 9, 10, 11, 12, and 13, the display device 1060 according to one or more embodiments might not include the penetration prevention member PP. In this case, the display device may also be defective by the liquid.

However, this is illustrative, and some of the components may be omitted from the display device 1060, and the display device 1060 may include additional other components.

For example, a color-changing layer may be included on top of the light-emitting layer EL. The color-changing layer may include a quantum dot. The quantum dot may be a material that converts a color light emitted from the light-emitting layer EL into other color light.

The method of driving the display device according to one or more embodiments of the present disclosure and the display device performing the same may detect a spillage of the liquid in advance. Through this, it is possible to inform (e.g. induce or advice) the user to wipe off the liquid or block power supply to prevent the occurrence of the defect caused by the liquid.

The present disclosure may be applied to a display device and an electronic device including the display device. For example, the present disclosure may be applied to computer, laptop, mobile phone, smart pad, PMP, PDA, MP3 player, and/or the like.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A method of driving a display device, the method comprising:
receiving input image data;
generating temperature information for each of areas of a display panel of the display device;
detecting a local temperature change based on the temperature information; and
determining whether the local temperature change is a change due to the input image data.

2. The method of claim 1, further comprising:
determining whether the local temperature change spreads in a longitudinal direction if the local temperature change is not the change due to the input image data; and
wherein the longitudinal direction is parallel to a direction in which liquid flows on the display panel.

3. The method of claim 2, further comprising:
displaying a warning window if the local temperature change spreads in the longitudinal direction is determined.

4. The method of claim 3,
wherein the warning window displays a message to remove liquid present in a first area of the areas of the display panel, and
wherein the first area is an area where the local temperature change spreads in the longitudinal direction.

5. The method of claim 2, further comprising:
blocking power supply to the display panel if the local temperature change spreads in the longitudinal direction is determined.

6. The method of claim 1, wherein:
the temperature information for each of the areas of the display panel comprises a first temperature information of a first area of the areas where liquid is present on the display panel and a second temperature information of at least one area of the areas of the display panel where the liquid is not present on the display panel; and
the first temperature information and the second temperature information have different values.

7. The method of claim 6, wherein the first temperature information has a smaller value than the second temperature information.

8. The method of claim 6, wherein:
the first temperature information is proportional to a first current value provided to a pixel at the first area; and
the second temperature information is proportional to a second current value provided to a pixel at a second area of the areas of the display panel.

9. A display device comprising:
a display panel comprising a plurality of pixels;
a power supply configured to supply power to the display panel; and
a controller configured to receive input image data, generate temperature information for each of areas of the display panel, detect a local temperature change based on the temperature information, and determine whether the local temperature change is a change due to the input image data.

10. The display device of claim 9,
wherein the controller is configured to determine whether the local temperature change spreads in a longitudinal direction if the local temperature change is not the change due to the input image data; and
wherein the longitudinal direction is parallel to a direction in which liquid flows on the display panel.

11. The display device of claim 10,
wherein the controller further comprises a warning part that is configured to display a warning window if the local temperature change spreads in the longitudinal direction is determined,
wherein the warning window is configured to display a message to remove liquid present in a first area of the areas of the display panel, and
wherein the first area is an area where the local temperature change spreads in the longitudinal direction.

12. The display device of claim 10,
wherein the controller further comprises a blocking part that is configured to block power supply to the display panel if the local temperature change spreads in the longitudinal direction is determined.

13. The display device of claim 9, wherein:
the temperature information for each of the areas of the display panel comprises a first temperature information of a first area of the areas where liquid is present on the display panel and a second temperature information of at least one area of the areas of the display panel where the liquid is not present on the display panel;
wherein the first temperature information has a smaller value than the second temperature information.

14. The display device of claim 13, wherein:
the first temperature information is proportional to a first current value provided to a pixel at the first area, and
the second temperature information is proportional to a second current value provided to a pixel at a second area of the areas of the display panel.

15. The display device of claim 9, further comprising:
a driving integrated circuit electrically connected with the display panel; and
a penetration prevention member sealing a gap between the display panel and the driving integrated circuit,
wherein each of the plurality of pixels comprises an organic light-emitting material.

16. An electronic apparatus comprising:
a display device including a display panel comprising a plurality of pixels;
a processor configured to control the display device;
a power supply configured to supply power to the display device; and
a controller configured to transmit input image data to the display panel, generate temperature information for each of areas of the display panel, detect a local temperature change based on the temperature information, and determine whether the local temperature change is a change due to the input image data.

17. The electronic apparatus of claim 16,
wherein the controller is configured to determine whether the local temperature change spreads in a longitudinal direction if the local temperature change is not the change due to the input image data,
wherein the controller is configured to commend to the display device to display a warning window including a message to remove liquid present in a first area of the areas of the display panel if the local temperature change spreads in the longitudinal direction is determined,
wherein the longitudinal direction is parallel to a direction in which liquid flows on the display panel, and
wherein the first area is an area where the local temperature change spreads in the longitudinal direction.

18. The electronic apparatus of claim 16,
wherein the controller is configured to determine whether the local temperature change spreads in a longitudinal direction if the local temperature change is not the change due to the input image data,
wherein the controller is configured to commend to the power supply to block power supply to the display panel if the local temperature change spreads in the longitudinal direction is determined, and
wherein the longitudinal direction is parallel to a direction in which liquid flows on the display panel.

19. The electronic apparatus of claim 16 wherein:
the temperature information for each of the areas of the display panel comprises a first temperature information of a first area of the areas where liquid is present on the display panel and a second temperature information of at least one area of the areas of the display panel where the liquid is not present on the display panel;
wherein the first temperature information has a smaller value than the second temperature information.

20. The electronic apparatus of claim 16, wherein:
the first temperature information is proportional to a first current value provided to a pixel at the first area; and
the second temperature information is proportional to a second current value provided to a pixel at a second area of the areas of the display panel.
